(19) United States
(12) Patent Application Publication
(10) Pub. No.: US 2005/0082615 A1
(43) Pub. Date: Apr. 21, 2005

(54) Epitaxial ferroelectric thin-film device and method of manufacturing the same

(75) Inventor: Tadahiro Minamikawa, Ritto-shi (JP)

Correspondence Address: DICKSTEIN, SHAPIRO, MORIN & OSHINSKY, LLP;41st Floor, 1177 Avenue of the Americas, New York, NY, 10036-2714, US

(73) Assignee: Murata Manufacturing Co., Ltd.

(21) Appl. No.: 11/002,798

(22) Filed: Dec. 3, 2004

Related U.S. Application Data
(63) Continuation of application No. 10/171,162, filed on Jun. 12, 2002.

(30) Foreign Application Priority Data
Jun. 12, 2001 (JP) 2001-176659
May 15, 2002 (JP) 2002-139930

(51) Int. Cl. H01L 27/01

(52) U.S. Cl. 257/347

(57) ABSTRACT

An amorphous film is formed on an oxide single crystal substrate having a perovskite structure at a temperature lower than a crystallization temperature thereof, and then the amorphous film is heated at a temperature higher than the crystallization temperature to be crystallized into a ferroelectric thin film having a perovskite structure. In a amorphous film formation step, a two-layered amorphous film composed of at least two layers different from each other in composition can also formed. The combination of amorphous film formation step and crystallization step can be repeated at least twice.

This is a continuation of application Ser. No. 10/171,165, filed Jun. 12, 2002.

### BACKGROUND OF THE INVENTION

1. Field of the Invention

The present invention relates to a ferroelectric thin-film device and a method of manufacturing the ferroelectric thin-film device, and in particular, to a ferroelectric thin-film device appropriate for use as a light-guide device such as an optical switch and a method of manufacturing the light-guide device.

2. Description of the Related Art

Ferroelectric materials have an electrooptical effect and a non-linear optical effect, and are used as an optical switch, an optical modulator, a second-harmonic device or other suitable device. These devices, conventionally using a single crystal such as LiNbO₃ or LiTaO₃, has a light-guide structure, formed by the thermal diffusion of Ti or protons, as a basic structure.

When the ferroelectric thin film is used for an optical device, a plurality of epitaxial thin films different from each other in composition is formed on a single crystal substrate in a light-guide structure. An optical switch, a low-driving voltage optical modulator, an optical integrated circuit or other suitable device is produced. To use the ferroelectric thin films for an optical device, however, the production of a thin film having a low propagation loss and optical performance as good as that of a single crystal is essentially required.

Known as a method of manufacturing a ferroelectric thin film are the MOCVD methods, the rf-magnetron sputtering method, a laser ablation method, or other suitable method to form epitaxial ferroelectric thin films fabricated of LiNbO₃, LiTaO₃, PZT, PbTiO₃, BaTiO₃ or other suitable films. When a thin film is grown using the vapor phase epitaxial growth method, the surface roughness of the film increases as the film increases. To use the film as a light guide, optical loss due to scattering on the film surface increases.

In a known method to improve the surface smoothness of a film, an amorphous LiNbO₃ thin film is formed on a sapphire substrate using the metal-organic chemical vapor deposition (MOCVD) under a temperature (for example, 470° C.) equal to or lower than the crystallization temperature thereof, and is then grown in a solid-phase epitaxial growth under a temperature equal to or higher than the crystallization temperature thereof.

To obtain a complete epitaxial film in the combination of the sapphire substrate and the ferroelectric material (LiNbO₃), an epitaxial film as thick as 50 to 100 nm serving as a buffer layer needs to be formed beforehand. This complicates the manufacturing process.

Available as another method to improve the surface smoothness is a solid-phase growth or sol-gel method in which a sol liquid of an organic metal compound is applied and is then subjected to a heat treatment to result in a thin film. The resulting epitaxial film has a smooth surface and a small optical loss due to scattering on the surface thereof.

A high concentration sol liquid can be subjected to a heat treatment without promoting hydrolysis. However, the thickness of a sol liquid coating must be about 100 nm or less per application cycle to obtain an epitaxial film excellent in crystallinity through the sol-gel method. A number of cycles of sol liquid application and heat treatment is required to form a film having a thickness of 3 μm which is needed to use the film as a light-guide thin-film device. The time required to apply and heat the sol liquid becomes long, and production yield thereof is low.

The light-guide thin film must have a laminate structure formed of layers having different refractive indexes to assure light tightness of the thin film. To this end, the refractive indexes are controlled by adjusting the compositions of each layer. The sol liquids containing different compositions must thus be adjusted, requiring a complex manufacturing process and leading to high manufacturing cost.

FIG. 5 illustrates a channel-type light-guide device including an oxide single crystal substrate S1 having a perovskite structure, a lower clad layer 21 formed on the oxide single crystal substrate S1 and having a channel 21a extending in the direction of light propagation, a core layer 22 arranged on the lower clad layer 21, and an upper clad layer 23 arranged on the core layer 22.

When the channel-type light-guide device having the aforementioned structure is produced, an epitaxial film serving as the core layer 22 is formed using the solid-phase epitaxial method, namely, the sol-gel method. The thickness of coat is limited, typically to 0.5 μm at maximum to assure crystallinity in the epitaxial film. The depth of the channel 21a is also limited to 0.5 μm or so, to assure crystallinity in the epitaxial film formed in the channel 21a.

In another method, an epitaxial film is formed on a substrate having a channel as deep as 0.5 μm or on a thin film on such a substrate using a liquid-phase epitaxial technique. In this case, however, the type of the epitaxial film is limited to a compound such as LiNbO₃. The liquid-phase epitaxial technique causes a material dislocation due to the evaporation of material. A dielectric oxide having a perovskite type structure, particularly, a compound such as PZT or PLZT having a high electrooptical coefficient, cannot be formed. It is thus extremely difficult to produce a channel-type light-guide device formed of a dielectric oxide having a perovskite structure with a channel depth of 0.5μ or more.

To connect a channel-type light-guide device to an optical fiber at the end face thereof, the thickness of the core layer of the light guide must be about 3 μm or more. Single-mode conditions must be satisfied to prevent loss involved in the introduction of multi-mode function. The thickness of the core layer to satisfy the single-mode conditions in the channel-type light guide depends on the depth of the channel. The deeper the channel, the thicker becomes the core layer. For example, when the difference in refractive index between the core layer and the lower clad layer is 0.010 in a light guide with the core layer having a refractive index of about 2.4, the thickness of the core layer satisfying the single-mode conditions with a channel depth of 5.0 μm is 5.0 μm. When the channel depth is less than 0.5 μm, the thickness of the core layer satisfying the single-mode conditions is less than 2.0 μm. The device cannot be connected to the optical fiber at the end face thereof.

### SUMMARY OF THE INVENTION

The present invention resolves the aforementioned problems, namely, the surface roughness of the film manufactured through the vapor epitaxial growth method, the film formation thickness requirement per application cycle in the sol-gel method, the complex manufacturing process required to fabricate the laminate structure of layers of different refractive indexes, and the core thickness requirement to satisfy the single-mode conditions under the channel depth limitation. It is an object of the present invention to provide a method of efficiently manufacturing an epitaxial ferroelectric thin-film device having excellent characteristics, and such an epitaxial ferroelectric thin-film device.

To achieve the above object, a preferred method of the present invention for manufacturing an epitaxial ferroelectric thin-film device includes an amorphous film formation step of forming an amorphous film on an oxide single crystal substrate having a perovskite structure at a temperature lower than a crystallization temperature of the amorphous film through a vapor phase epitaxy method, and a crystallization step of crystallizing the amorphous film into a ferroelectric thin film having a perovskite structure by heating the amorphous film at a temperature higher than the crystallization temperature.

When a thick film (100 nm or thicker) is formed in a single cycle in the amorphous film formation step, the epitaxial ferroelectric film is then formed by the heat treatment. The manufacturing process is simplified and costs are reduced.

Moreover, the thickness of the film per film formation cycle is large. The chance of inclusion of organic materials is small. An epitaxial film having a large volume ratio of inorganic component results.

An epitaxial ferroelectric thin-film device having a smooth surface and excellent crystallinity is obtained without the need for the buffer layer.

In accordance with the present invention, the oxide single crystal substrate may be any of a variety of substrates fabricated of a material that allows a film to be epitaxially crystallized thereon. For example, an SrTiO₃ single crystal substrate having a perovskite structure or an R surface sapphire single crystal substrate having a different crystalline structure with a perovskite structure epitaxially crystallized thereon in a (101) direction are preferable.

The oxide single crystal substrate serving an underlayer of the ferroelectric thin film having the perovskite structure may be an electrically conductive single crystal substrate such as an SrTiO₃ substrate doped with Nb or La. An electrically conductive thin film of SrRuO₃ epitaxially oriented with the R surface sapphire substrate (101) may be used as an underlayer. In the broad context of the present invention, the oxide single crystal substrate serving the underlayer includes an electrically conductive thin film such as SrRuO₃ epitaxially oriented on the R surface sapphire substrate (101).

In accordance with another preferred embodiment, the thickness of the amorphous film formed in the amorphous film formation step may fall within a range of from about 200 to 5000 nm.

After being formed on the oxide single crystal substrate having a perovskite structure at the temperature lower than the crystallization temperature through the vapor phase epitaxy method, the amorphous film is crystallized into the ferroelectric thin film having a perovskite structure by heating the amorphous film at the temperature higher than the crystallization temperature. Even when the film having a thickness falling within a range of about 200 to 5000 nm is formed in a single film formation step, the epitaxial film is successfully produced through the heat treatment. The manufacturing process is thus simplified, and manufacturing costs are reduced.

The refractive index of the amorphous film formed in the amorphous film formation step subsequent to crystallization may be larger than the refractive index of the oxide single crystal substrate. With this characteristic, a epitaxial ferroelectric thin-film device free from light leakage to the substrate and appropriate for use as a light-guide device is obtained.

In accordance with another preferred embodiment, the amorphous film formed in the amorphous film formation step may include at least two layers different from each other in composition. With this characteristic, an epitaxial film having a laminate structure composed of the layers different from each other in refractive index is obtained through the heat treatment. This arrangement allows a light-guide epitaxial film requiring a laminate structure composed of a plurality of layers having different refractive indices to be efficiently produced.

In accordance with yet another preferred embodiment, the temperature of the oxide single crystal substrate may fall within a range of from about 300 to 500° C. in the amorphous film formation step. With this characteristic, no undissolved organic substances nor carbon atoms reside in the film. The amorphous film is thus efficiently crystallized in an epitaxial film in the subsequent crystallization process.

In accordance with another preferred embodiment, subsequent to the amorphous film formation step and the crystallization step, the amorphous film formation step and crystallization step may be repeated at least one more time. When the amorphous film formation step and the crystallization step are repeated at least one cycle, a thick amorphous film is formed. By subjecting the amorphous film to the heat treatment, a thick epitaxial ferroelectric thin-film device is efficiently manufactured.

The vapor phase epitaxy method may be a metal organic chemical-vapor deposition in accordance with another preferred embodiment, and the film formation rate of the film may fall within a range of from about 10 to 500 nm/m. The use of the metal organic chemical-vapor deposition (MOCVD) method, which results in a larger film formation rate than other vapor phase epitaxy methods, allows a film formation rate falling within a range of from about 10 to 500 nm/m to be achieved. High film formation efficiency thus results.

Moreover, the compositions of the film can be controlled with the MOCVD method by changing the amount of supply of material in the middle of film formation. The refractive index of the resulting epitaxial film is thus modified and controlled. This arrangement allows a light-guide epitaxial film requiring a laminate structure composed of a plurality of layers having different refractive indices to be efficiently produced.

The amount of the supply of a material may be controlled in the middle of film formation by changing the amount of a carrier gas supplied to a container of the material or by adjusting the pressure or temperature in the container to change the evaporation rate of the material. Other methods may be used to control the supply of the material.

In accordance with another preferred embodiment, the method of manufacturing an epitaxial ferroelectric thin-film device may further include a first amorphous film formation step of forming an amorphous film as a lower clad layer on an oxide single crystal having a perovskite structure at a temperature lower than the crystallization temperature of the amorphous film through a vapor phase epitaxy method, a first crystallization step of crystallizing the amorphous film into a ferroelectric thin film having a perovskite structure as a lower clad layer by heating the lower clad layer amorphous film at a temperature higher than the crystallization temperature thereof, a step of forming a channel on the top surface of the lower clad layer in the direction of light propagation, a second amorphous film formation step of forming an amorphous film as a core layer on the top surface of the lower clad layer at a temperature lower than the crystallization temperature of the amorphous film through a vapor phase epitaxy method, and a second crystallization step of crystallizing the core layer amorphous film into a ferroelectric thin film having a perovskite structure as the core layer by heating the core layer amorphous film at a temperature higher than the crystallization temperature thereof.

Thus, after the amorphous film as the lower clad layer is formed on the oxide single crystal having the perovskite structure at the temperature lower than the crystallization temperature through a vapor phase epitaxy method, the amorphous film is crystallized into the ferroelectric thin film having the perovskite structure as the lower clad layer by heating the lower clad layer amorphous film at the temperature higher than the crystallization temperature. After a channel is extended on the top surface of the lower clad layer, an amorphous film as the core layer is formed on the top surface of the lower clad layer at the temperature lower than the crystallization temperature through the vapor phase epitaxy method. The core layer amorphous film is then crystallized into the ferroelectric thin film having the perovskite structure as the core layer by heating the core layer amorphous film at the temperature higher than the crystallization temperature. Even when the channel is set to be as deep as 0.5 μm, the core layer amorphous film is reliably epitaxially crystallized. In this way, the lower clad layer and the core layer (ferroelectric layers), each excellent in epitaxial crystallinity and surface smoothness, and having the perovskite structure, are reliably obtained. A channel type thin-film light-guide device having a channel as deep as 0.5 μm, connectable with an optical fiber at the device end face thereof, is efficiently manufactured.

An epitaxial ferroelectric thin-film device of the preferred present invention includes an oxide single crystal having a perovskite structure and a ferroelectric thin film having a perovskite structure that is crystallized by heating at a temperature higher than a crystallization temperature of an amorphous film, the amorphous film having formed on the oxide single crystal through a vapor phase epitaxy method at a temperature lower than the crystallization temperature thereof.

The epitaxial ferroelectric thin-film device of the present invention includes the oxide single crystal having the perovskite structure and a ferroelectric thin film having the perovskite structure that has a flat surface and high crystallization, crystallized the amorphous film that is formed on the oxide single crystal through the vapor phase epitaxy method at the temperature lower than the crystallization temperature by heating at the temperature higher than the crystallization temperature. The epitaxial ferroelectric thin-film device suffers from less optical loss due to the light scattering on the surface of the film, and is appropriate for use as an optical device.

The epitaxial ferroelectric thin-film device of the present invention is thus efficiently manufactured through the methods described above.

In accordance with another preferred embodiment, the refractive index of the ferroelectric thin film having the perovskite structure may be larger than the refractive index of the oxide single crystal substrate. With this characteristic, the epitaxial ferroelectric thin-film device free from light leakage to the substrate and appropriate for use as a light-guide device is obtained.

In accordance with another preferred embodiment, the refractive index of the ferroelectric thin film having the perovskite structure may include at least two layers different from each other in composition. With this characteristic, a light-guide epitaxial film requiring a laminate structure composed of a plurality of layers having different refractive indices is efficiently produced.

In accordance with another preferred embodiment, the ferroelectric thin film having the perovskite structure may includes a first layer and a second layer different from each other in composition, and the refractive index of the second layer may be larger than the refractive index of the first layer. Even when a substrate not transparent to propagating light is used, a light-guide epitaxial film is efficiently manufactured.

In accordance with yet another preferred embodiment, the ferroelectric thin film having the perovskite structure may include at least three layers different from each other in composition, wherein the layer having the highest refractive index is sandwiched between the remaining two layers, each having a refractive index lower than the highest refractive index of the one layer. With this characteristic, even when a substrate not transparent to propagating light is used on the epitaxial ferroelectric thin film, a light-guide epitaxial film free from optical loss is efficiently manufactured.

In accordance with another preferred embodiment, an epitaxial ferroelectric thin-film device of the present invention includes an oxide single crystal substrate having a perovskite structure, a lower clad layer having a channel as deep as or deeper than 0.5 μm and extending in the direction of light propagation, and formed of a ferroelectric thin film which has a perovskite structure and is crystallized by heating, at a temperature higher than a crystallization temperature of an amorphous film which is formed on the oxide single crystal substrate at a temperature lower than the crystallization temperature through a vapor phase epitaxy method, and a core layer formed of a ferroelectric thin film which has a perovskite structure and is crystallized by heating at a temperature higher than a crystallization temperature of an amorphous film which is formed on the lower clad layer at a temperature lower than the crystallization temperature thereof through a vapor phase epitaxy method.

This epitaxial ferroelectric thin-film device includes the oxide single crystal substrate having the perovskite structure, the lower clad layer having the channel as deep as or deeper than 0.5 μm and extending in the direction of light propagation, and formed of the ferroelectric thin film which has the perovskite structure and is crystallized by heating at a temperature higher than the crystallization temperature of the amorphous film which is formed on the oxide single crystal substrate at the temperature lower than the crystallization temperature through the vapor phase epitaxy method, and the core layer formed of the ferroelectric thin film which has the perovskite structure and is crystallized by heating, at the temperature higher than the crystallization temperature, the amorphous film which is formed on the lower clad layer at the temperature lower than the crystallization temperature through the vapor phase epitaxy method. The channel as deep as 0.5 μm is formed in the lower clad layer. The lower clad layer and the core layer formed on the lower clad layer are ferroelectric thin films, each excellent in epitaxial crystallinity and surface smoothness, and having the perovskite structure. Thus, a channel-type thin-film light-guide device connectable with an optical fiber at the end face thereof is provided.

The epitaxial ferroelectric thin-film device as the channel-type thin-film light-guide is thus efficiently manufactured through the methods described above.

In accordance with another preferred embodiment, the difference between the refractive index Δn of the core layer and the refractive index of the lower clad layer in the epitaxial ferroelectric thin-film device may fall within a range of 0.005<Δn<0.015 when the epitaxial ferroelectric thin-film device includes the epitaxially crystallized core layer on the lower clad layer having the channel having a depth of 0.5 μm or more, and this structure allows the single-mode conditions to be satisfied. This range is not achieved in the conventional art. This arrangement provides a core thick enough to allow the core to be coupled with an optical fiber.

Other features, elements, characteristics and advantages of the present invention will become more apparent from the following detailed description of preferred embodiments of the present invention with reference to the attached drawings.

### BRIEF DESCRIPTION OF THE DRAWINGS

FIG. 1 is an XRD diffraction pattern of a PZT thin film formed on a SrTiO₃ substrate in accordance with a first method embodiment of the present invention;

FIG. 2 is a polar diagram of the PZT thin film formed on the SrTiO₃ substrate in accordance with the method of the first embodiment of the present invention;

FIG. 3 diagrammatically illustrates a PZT thin film formed of two layers different in composition on a SrTiO₃ substrate in accordance with a second method embodiment of the present invention;

FIG. 4 diagrammatically illustrates a PZT thin film formed on a SrTiO₃ substrate through two cycles of a film formation and a heat treatment in accordance with a third method embodiment of the present invention;

FIG. 5 is a cross-sectional view conceptually illustrating the construction of a channel-type thin-film light-guide device; and

FIG. 6 plots the relationship of the depth of a channel formed in a lower clad layer and the thickness of a core layer that satisfies single-mode conditions.

### DESCRIPTION OF THE PREFERRED EMBODIMENTS

The embodiments of the present invention will now be discussed in detail.

First Embodiment

Formation of Amorphous Film

An amorphous film is first formed on an oxide single crystal substrate having a perovskite structure at a temperature lower than the crystallization temperature of the film through the vapor-phase epitaxy method, namely, the MOCVD method.

The oxide single crystal substrate having the perovskite structure (hereinafter simply referred to as “substrate”) used is preferably an SrTiO₃ substrate or an electronically conductive SrTiO₃ substrate doped with Nb or La, each of which has a lattice constant smaller than the lattice constant of a perovskite ferroelectric film formed on the substrate. Other oxide single crystal substrates having the perovskite structure may be used.

The oxide single crystal substrate has the same crystal structure as that of the film. Compared with the case in which a substrate and a film are different from each other in crystal structure, the difference in lattice constant between the substrate and the film becomes small. The epitaxial crystallization is easy to achieve.

When a substrate has a lattice constant smaller than that of a thin film, the crystal lattice of the thin film in an axis in parallel with the substrate is reduced. Along with this, the axis perpendicular to the substrate is stretched, and the polarization axis tends to be oriented perpendicular to the substrate.

The material of the amorphous film is preferably a metal alkoxide or a metallic salt of, e.g., Ba, Sr, Pb, La, K, Ti, Zr, Nb and Ta.

When the thickness of the film is set to be about 10,000 nm or less per amorphous film formation cycle, an epitaxial film having excellent surface smoothness and excellent crystallinity is obtained through the subsequent heat treatment process. To obtain a film having an excellent epitaxial crystallinity, the thickness thereof is preferably about 5,000 nm or less.

When the thickness of the film is set to be smaller than about 30 nm per amorphous film formation cycle, the film has an island surface texture in the course of crystallization through the heat treatment, and the surface smoothness is destroyed. For this reason, the thickness of the film per amorphous film formation cycle is preferably about 30 nm or more.

From the standpoint of film formation costs, the thickness of the film per amorphous film formation cycle is preferably about 200 nm or more.

The film formation rate of the film is preferably about 200 nm/m or less. From the standpoint of forming a film excellent in surface smoothness and crystallinity, the film formation rate is preferably about 100 nm/m or less.

The temperature of the substrate in the amorphous film formation is preferably within a range of from about 300 to 500° C. If the substrate temperature drops below about 300° C., undissolved organic substances and carbon atoms reside in the film. If the substrate temperature rises above about 500° C., the film starts crystallizing during the film formation.

The present invention is detailed below by comparing examples with comparative examples.

### EXAMPLE 1

In example 1, an amorphous film was formed on a substrate through the MOCVD method. The amorphous film was then crystallized into an epitaxial ferroelectric thin-film device through a heat treatment.

(1) After two hours of heat treatment at 1000° C. in air, an SrTiO₃ (001) substrate (an oxide single crystal substrate having a perovskite structure) was cleaned in a solvent, rinsed and was then subjected to a drying operation.

(2) Materials such as Pb(DPM)₂, Zr(O-t-Bu)₄ and Ti(O-i-Pr)₄ were set into a vaporizer. By adjusting the temperature of the vaporizer and a flow rate of a carrier gas, an amorphous film fabricated of PbZr_{0.6}Ti_{0.4}O₃ (PZT) was formed to a thickness of 750 nm on the SrTiO₃(001) substrate heated to 400° C. at a film formation rate of 40 nm/m.

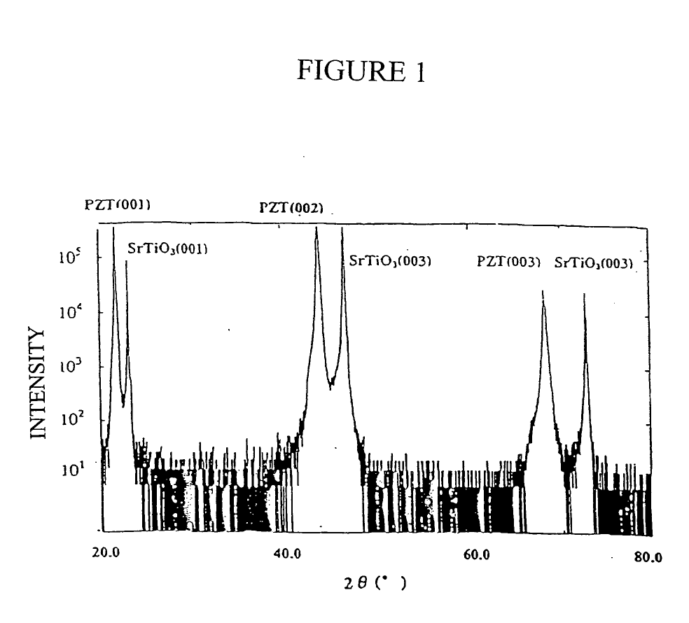

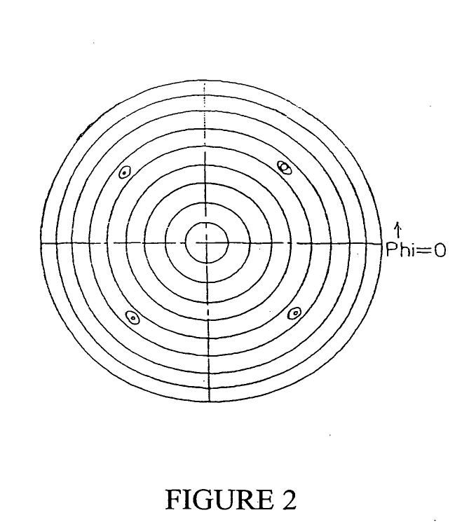

(3) The amorphous film and the substrate were heated to 700° C. at a temperature rise rate of 50° C./s in an oxygen bath, and held at 700° C. for 15 minutes, and was then subjected to a cooling operation at a temperature fall rate of 10° C./s. An amorphous film was crystallized into a PZT film. An XRD diffraction pattern of the resulting PZT film is shown in FIG. 1, and a polar diagram thereof is shown in FIG. 2.

Referring to FIG. 1, a diffraction peak of the PZT thin film is found in those related to the direction of plane (001). The polar diagram shown in FIG. 2 shows that the PZT thin film has a regularly oriented fourfold symmetry, namely, is three-axis oriented. The rocking curve width of the thin film is 0.17°.

These results shows that the PZT thin film produced through the manufacturing method of the epitaxial ferroelectric thin-film device of the present invention has an excellent crystallinity.

The surface roughness of the epitaxial PZT thin film obtained in the example 1 is Rms=1.7 nm and R_{MAX}=8 nm. The PZT film thus has an excellent surface smoothness.

In response to light of a wavelength of 633 nm, the refractive index of the epitaxial PZT thin film obtained in the example 1 is 2.54, which is larger than a refractive index of 2.40 of a SrTiO₃ substrate.

### EXAMPLE 2

In example 2, the supply rate of a carrier gas was changed in the middle of the amorphous film formation step, and an epitaxial ferroelectric thin-film device fabricated of two layers which were different from each other in composition was manufactured.

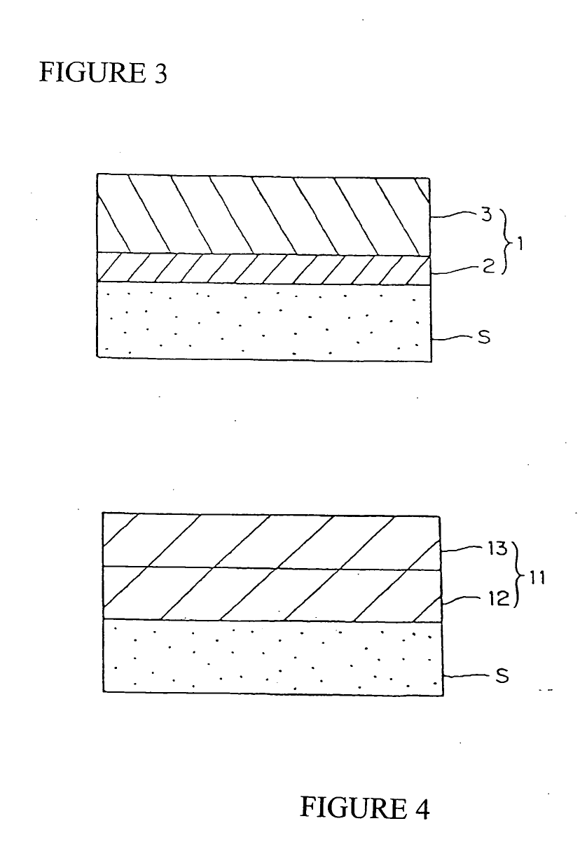

An amorphous film was formed in the same way as that of the example 1. In the course of the amorphous film formation step, the supply rate of the carrier gas to a material was changed to change the evaporation rate of the material. An amorphous film of two layers having different compositions was formed and then was subjected to a heat treatment for crystallization. As diagrammatically shown in FIG. 3, a two-layered epitaxial ferroelectric thin film 1 formed of two layers, a first (lower) layer 2 and a second (upper) layer 3, of different compositions was thus formed on a substrate S.

The first (lower) layer 2 forming the epitaxial ferroelectric thin film 1 in example 2 has a composition of Pb_{0.91}La_{0.09}Zr_{0.65}Ti_{0.35}O₃ and is as thick as 1,000 nm. The second (upper) layer 3 has a composition of PbZr_{0.66}Ti_{0.45}O₃, and is as thick as 1,000 nm. The overall thickness of the epitaxial ferroelectric thin film 1 is 2,000 nm.

The crystallinity of the two-layered epitaxial ferroelectric thin film 1 was tested. Like the thin film in the example 1, the epitaxial ferroelectric thin film 1 in the example 2 has a three-axis oriented epitaxial thin film.

The rocking curve half width of the epitaxial film is 0.21°, and the surface roughness thereof is Rms=1.3 nm and R_{MAX}=7 nm.

In the course of the amorphous film formation step, the supply of the carrier gas to the material has been modified to change the evaporation rate of the material. The two-layered epitaxial ferroelectric thin film 1 having the first layer 2 and the second layer 3 proved to be excellent in crystallinity and surface smoothness.

In response to light of a wavelength of 633 nm, the first layer 2 of the epitaxial ferroelectric thin film 1 in the example 2 has a refractive index of 2.47 and the second layer 3 has a refractive index 2.56. The second layer 3 is larger in refractive index than the first layer 2.

### EXAMPLE 3

In example 3, two cycles of amorphous film formation and heat treatment were carried out to result in a thick epitaxial ferroelectric thin film.

As in the example 1, the amorphous film formation step and the heat treatment step were carried out. Another amorphous film formation step and another heat treatment step were carried out (in other words, the cycle of amorphous film formation step and heat treatment step was performed for two times). As diagrammatically shown in FIG. 4, a PbZr_{0.6}Ti_{0.4}O₃ layer (a first (lower) layer) 12 having a thickness of 1000 nm was formed on a substrate S in the first cycle, and a PbZr_{0.6}Ti_{0.4}O₃ (a second (upper) layer) 13 having a thickness of 1,000 was formed on the first (lower) layer 12. A PbZr_{0.6}Ti_{0.4}O₃ thin film (epitaxial ferroelectric thin film) 11 having an overall thickness of 2,000 nm was obtained.

The resulting PbZr_{0.6}Ti_{0.4}O₃ thin film was tested in terms of crystallinity. Like in examples 1 and 2, the thin film proved to be a three-axis oriented epitaxial thin film.

The rocking curve half width of the epitaxial ferroelectric thin film 11 is 0.24°, and the surface roughness thereof is Rms=1.9 and R_{MAX}=9 nm.

The epitaxial ferroelectric thin film 11 was produced by repeating the amorphous film formation step and the heat treatment twice to result in a thick epitaxial ferroelectric thin film. Such a epitaxial ferroelectric thin film is also excellent in crystallinity and surface smoothness.

In response to light of a wavelength of 633 nm, the epitaxial PZT thin film in the example 3 has a refractive index of 2.54.

As described above, the amorphous film (having an elemental structure of the perovskite when crystallized at a temperature equal to or higher than the crystallization temperature) is formed on the oxide single crystal substrate having a perovskite structure through the vapor phase epitaxy at a temperature equal to or lower than the crystallization temperature. The amorphous film is then crystallized at a temperature equal to or higher than the crystallization temperature. Without the need for a buffer layer, the epitaxial ferroelectric thin film excellent in surface smoothness and crystallinity results.

The method of the present invention results in a film thickness larger than that achieved by the sol-gel method. As described in connection with the example 2, the supply rate of the carrier gas to the material can be modified to change the evaporation rate of the material in the course of the amorphous film formation step. An epitaxial ferroelectric thin film formed of a plurality of layers different in refractive index is thus produced by one cycle of film formation. The epitaxial ferroelectric thin film is thus efficiently manufactured.

### COMPARATIVE EXAMPLE 1

Comparative example 1 is identical to the example 1 except that an oxide substrate (an R sapphire (012) substrate) having no perovskite structure was used. A PZT thin film was crystallized on the R sapphire substrate.

The PZT thin film thus produced has a (001) diffraction peak although the thin film is predominantly oriented at a (011) direction. The degree of orientational order in the (011) direction is 98%.

### COMPARATIVE EXAMPLE 2

Comparative example 2 is identical to the example 1 except that the substrate temperature was 550° C. in the amorphous film formation step. A crystallized PZT thin film was formed on the substrate.

The PZT thin film in the comparative example 2 has no crystallization peak found in the XRD diffraction pattern thereof and proved to be an amorphous film. The PZT thin film subsequent to the heat treatment has a (011) diffraction peak. The degree of orientational order in the (001) direction is 99%.

The surface roughness of the PZT thin film is Rms=5.3 nm and R_{MAX}=2⁸ nm.

When the substrate temperature was raised to 550° C. or higher in the amorphous film formation step in the comparative example 2, the PZT thin film in the comparative example 2 was outperformed by its counterpart in the examples 1 through 3 in epitaxial crystallinity and surface smoothness.

Second Embodiment

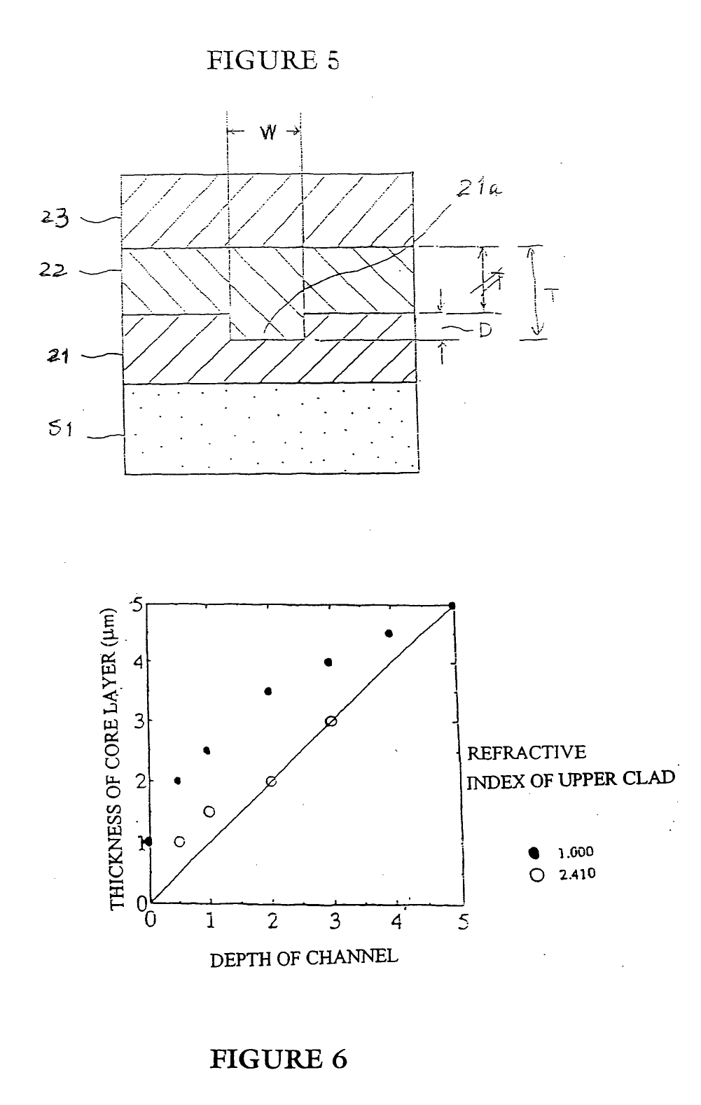

Referring to FIG. 5, a channel-type light-guide device of a second embodiment is discussed below. The channel-type light-guide includes an oxide single crystal substrate S1 having a perovskite structure, a lower clad layer 21 having a channel 21a with a width W running in the direction of light propagation, and formed on the oxide single crystal substrate S1, a core layer 22 formed on the lower clad layer 21, and an upper clad layer 23 formed on the core layer 22.

(1) An amorphous film as the lower clad layer was formed on the oxide single crystal substrate S1 having the perovskite structure at a temperature lower than the crystallization temperature thereof through the MOCVD method.

The oxide single crystal substrate S1 is of the type which enables a film to be epitaxially crystallized thereon. For example, when the amorphous film as the lower clad layer is an SrTiO₃ substrate, an SrTiO₃ single crystal having the same perovskite structure or an R surface sapphire single crystal substrate having a different crystal structure on which a perovskite compound is epitaxially crystallized in the (101) direction may be used.

Also, an electrically conductive single crystal substrate such as an SrTiO₃ doped with Nb or La may be used as the oxide single crystal substrate S1 serving as an underlayer for the lower clad layer 21. An electrically conductive thin film of SrRuO₃ epitaxially oriented on an R sapphire substrate (101) may be used as an underlayer for the lower clad layer.

(2) An amorphous film as the lower clad layer was crystallized into an epitaxial ferroelectric thin film 21 having the perovskite structure by heating the amorphous film at a temperature higher than the crystallization temperature.

(3) The channel 21a is formed on the top surface of the lower clad layer 21 in the direction of light propagation. In the second embodiment, the channel 21a having a width W of about 5 μm and an appropriate depth D of 0.5 μm or deeper is formed using a photolithography and etching processes. The etching process may be dry etching or wet etching.

(4) An amorphous film as the core layer is then formed on the top surface of the lower clad layer 21 on the MOCVD at a temperature lower than the crystallization temperature.

(5) The amorphous film as the core layer is then heated at a temperature higher than the crystallization temperature for crystallization, and then, the epitaxial ferroelectric thin film having the perovskite structure is formed as the core layer 22. A step present near the channel 21a when the core layer 22 is formed is removed by polishing, photolithography, or etching process. The core layer 22 is thus planarized on the top surface thereof. The etching process may be dry etching or wet etching.

The composition and type of the perovskite compounds of the core layer 22 and the lower clad layer 21 are properly selected so that the difference Δn in refractive index therebetween falls within a range of 0.005<Δn<0.015.

The perovskite compounds of the core layer 22 are PZT or PZLT, for example.

When PZT or PLZT is used as a perovskite compound for the core layer 22, the refractive index of PZT or PLZT has a larger refractive index with an increase in the value of Ti/(zr+Ti). The perovskite compound for the lower clad layer 21 is preferably a perovskite compound having a Ti/(zr+Ti) value smaller than that of the perovskite compound of the core layer 22, or a (PbBaSr)TiO₃ solid solution.

(6) An amorphous film as the upper clad layer is formed on the core layer 22 at a temperature lower than the crystallization temperature through the MOCVD method.

(7) The amorphous film as the upper clad layer is crystallized into a ferroelectric thin film having the perovskite structure as the upper clad layer 23 by heating the amorphous film at the temperature higher than the crystallization temperature.

The upper clad layer 23 is smaller in refractive index than the core layer 22, and is transparent to propagating light. For example, the upper clad layer 23 may be a thin film fabricated of the same compound as that of the lower clad layer 21, or may be air or an ITO thin film functioning as a transparent electrode.

The present invention is described further in detail with reference to examples and comparative examples.

### EXAMPLE 4

A channel-type thin-film light-guide device of an example 4 has the following parameter values:
(a) Refractive index of a core layer 22 to light of a wavelength of 1.55 μm: 2.420
(b) Refractive index of a lower clad layer 21 to light of a wavelength of 1.55 μm: 2.410
(c) Difference Δn between the refractive indices of the core layer 22 and the lower clad layer 21: 0.010
(d) Width (W) of a channel 21a formed in the lower clad layer 21: 5 μm
(e) Depth (D) of the channel 21a formed in the lower clad layer 21: 3 μm.

In the channel-type thin-film light-guide device having the parameter values (a) through (e), the thickness T of the core layer 22 satisfying the single-mode conditions is 4.0 μm when the upper clad layer 23 is air with the refractive index thereof being 1.000. The thickness T of the core layer 22 satisfying the single-mode conditions (T=4.0 μm) is the one that allows the core layer 22 to be coupled with an optical fiber (not shown).

FIG. 6 plots the relationship of the depth D of the channel 21a formed in the lower clad layer 21 and the thickness T of the core layer 22 that satisfies single-mode conditions under the above-listed parameters, wherein the upper clad layer 23 is a ferroelectric thin film having a refractive index of 2.410 and air having a refractive index of 1.000.

Relationship Between the Depth of the Channel and the Thickness of the Core Layer Satisfying the Single-Mode Conditions

Discussed next is the relationship between the depth of the channel and the thickness of the core layer satisfying the single-mode conditions. Given the same parameter values (a), (b), (c), and (d) with (e) depth D of the channel 21a changed from 3 μm to 0.5 μm, the thickness T of the core layer 22 satisfying the single-mode conditions is 2.0 μm when the upper clad layer 23 is air having a refractive index of 1.000.

When the depth D of the channel 21a formed in the lower clad layer 21 is 0.5 μm, the thickness T (T=2.0 μm) of the core layer 22 satisfying the single-mode conditions presents difficulty in coupling the core layer 22 with the optical fiber (not shown). As shown in FIG. 6, however, the thickness of the core layer 22 satisfying the single-mode conditions is increased by increasing the depth D of the channel 21a (for example, D=3 μm) (when the upper clad layer 23 is air, the thickness of the core layer 22 satisfying the single-mode conditions is set to be 4 μm). The core layer 22 is thus coupled with the optical fiber (not shown).

### COMPARATIVE EXAMPLE 3

A channel-type thin-film light-guide device in a comparative example 3 has the following parameter values.

(a) Refractive index of a core layer 22 to light of a wavelength of 1.55 μm: 2.420
(b) Refractive index of a lower clad layer 21 to light of a wavelength of 1.55 μm: 2.415
(c) Difference Δn between the refractive indices of the core layer 22 and the lower clad layer 21: 0.005 (d) Width (W) of a channel 21a formed in the lower clad layer 21: 5 μm.

The channel-type thin-film light-guide device in the third comparative example has the parameter values (a) through (d) with the difference Δn between the refractive indices of the core layer 22 and the lower clad layer 21 being 0.005. The thickness T of the core layer 22 satisfying the single-mode conditions is 11 μm at maximum, thus equal to the depth D of the channel 21a when the upper clad layer 23 is air with the refractive index thereof being 1.000.

When the depth of the channel 21a is 0.5 μm, the thickness T of the core layer 22 satisfying the single-mode conditions is 5.5 μm. In this arrangement, the core layer 22 can be coupled with the optical fiber.

With the refractive index difference Δn being 0.05 or less, the comparative example 3 has no particular advantage over the channel-type light guide with a channel as deep as 0.5 μm, which is achieved by the sol-gel method.

### COMPARATIVE EXAMPLE 4

A channel-type thin-film light-guide device in a comparative example 4 has the following parameter values.
(a) Refractive index of a core layer 22 to light of a wavelength of 1.55 μm: 2.420
(b) Refractive index of a lower clad layer 21 to light of a wavelength of 1.55 μm: 2.400
(c) Difference Δn between the refractive indices of the core layer 22 and the lower clad layer 21: 0.020
(d) Width (W) of a channel 21a formed in the lower clad layer 21: 5 μm.

The channel-type thin-film light-guide device in the third comparative example has the parameter values (a) through (d) with the difference Δn between the refractive indices of the core layer 22 and the lower clad layer 21 being 0.020. The thickness T of the core layer 22 satisfying the single-mode conditions is 2.5 μm at maximum.

When the difference Δn between the refractive indices of the core layer 22 and the lower clad layer 21 is 0.020 or more, the thickness T of the core layer 22 satisfying the single-mode conditions and permitting a good coupling with the optical fiber is difficult to achieve. The difference of this level is not preferable.

The difference Δn between the refractive indices of the core layer 22 and the lower clad layer 21 preferably falls within a range 0.005<Δn<0.015.

The present invention is not limited to the above-referenced embodiments, and a variety of changes and modifications in specific conditions of the amorphous film formation step and the crystallization step is possible within the scope of the present invention.

1. A method of manufacturing an epitaxial ferroelectric thin-film device, the method comprising forming an amorphous film having a crystallization temperature on an oxide single crystal substrate having a perovskite structure at a temperature lower than the crystallization temperature through vapor phase epitaxy, and
crystallizing the amorphous film in the configuration so formed into a ferroelectric thin film having a perovskite structure by heating the amorphous film in the configuration so formed at a temperature of at least the crystallization temperature.

2. A method of manufacturing an epitaxial ferroelectric thin-film device according to claim 1, wherein the amorphous film is formed to a thickness of about 50 to 10,000 nm.

3. A method of manufacturing an epitaxial ferroelectric thin-film device according to claim 1, wherein the composition of the amorphous film or the crystallization conditions, or both, is such that the refractive index of the crystallized film is larger than the refractive index of the oxide single crystal substrate.

4. A method of manufacturing an epitaxial ferroelectric thin-film device according to claim 1, wherein a second amorphous film having a crystallization temperature is formed at a temperature below its crystallization temperature on the first amorphous film prior to crystallization, the second amorphous film having a composition which is different from that of the first amorphous film, and the crystallization is by heating at a temperature of at least the higher of the two crystallization temperatures.

5. A method of manufacturing an epitaxial ferroelectric thin-film device according to claim 1, wherein the temperature is about 300 to 500° C. during amorphous film formation.

6. A method of manufacturing an epitaxial ferroelectric thin-film device according to claim 1, wherein the amorphous film formation and the crystallization are repeated at least once.

7. A method of manufacturing an epitaxial ferroelectric thin-film device according to claim 6, wherein a channel oriented in the direction of light propagation is formed on a surface of the first formed crystallized layer prior to said repetition.

8. A method of manufacturing an epitaxial ferroelectric thin-film device according to claim 1, wherein the vapor phase epitaxy is metal organic chemical-vapor deposition at a film formation rate of about 10 to 500 nm/m.

9. A method of manufacturing an epitaxial ferroelectric thin-film device according to claim 1, wherein the amorphous film before crystallization has a thickness of about 200 to 5,000 nm and is formed by depositing the film at a film formation rate of up to about 100 nm/m and a temperature of about 300 to 500° C.

10. A method of manufacturing an epitaxial ferroelectric thin-film device according to claim 1, wherein the substrate comprises SrTiO₃.

11. A method of manufacturing an epitaxial ferroelectric thin-film device, the method comprising forming an amorphous film having a crystallization temperature on an oxide single crystal substrate having a perovskite structure at a temperature lower than the crystallization temperature through vapor phase epitaxy, and
without removing a portion of the amorphous film as so formed, crystallizing the amorphous film into a ferroelectric thin film having a perovskite structure by heating the amorphous film in the configuration so formed at a temperature of at least the crystallization temperature.

12. An epitaxial ferroelectric thin-film device comprising:
a perovskite structure oxide single crystal substrate having a ferroelectric thin film having a perovskite structure thereon,
wherein the ferroelectric thin film is a heat crystallized vapor phase epitaxy amorphous film.

13. An epitaxial ferroelectric thin-film device according to claim 12, wherein the refractive index of the ferroelectric thin film having the perovskite structure is larger than the refractive index of the oxide single crystal substrate.

14. An epitaxial ferroelectric thin-film device according to claim 12, wherein the ferroelectric thin film having the perovskite structure comprises at least two layers of ferroelectric thin film having the perovskite structure which are different from each other in composition.

15. An epitaxial ferroelectric thin-film device according to claim 12, wherein the ferroelectric thin film having the perovskite structure comprises at least three superposed layers, and wherein the ferroelectric thin film layer which is sandwiched between the other two layers has the highest refractive index of the three layers.
